(19) United States
(12) Patent Application Publication
(10) Pub. No.: US 2005/0120945 A1
(43) Pub. Date: Jun. 9, 2005

(54) Quartz crucibles having reduced bubble content and method of making thereof

(75) Inventor: Richard L. Hansen, Mentor, OH (US)

Correspondence Address: GEAM - QUARTZ;IP LEGAL, ONE PLASTICS AVENUE, PITTSFIELD, MA, 01201-3697, US

(73) Assignee: General Electric Company

(21) Appl. No.: 11/002,597

(22) Filed: Dec. 2, 2004

Related U.S. Application Data
(60) Provisional application No. 60/526,484, filed on Dec. 3, 2003.

(51) Int. Cl. C30B 15/00; C30B 21/06; C30B 27/02; C30B 28/10; C30B 30/04

(52) U.S. Cl. 117/15

(57) ABSTRACT

A quartz crucible having reduced/controlled bubble content is disclosed, comprising an outer layer and an inner layer doped with elements and compounds that: a) react with oxygen and nitrogen at or near the fusion temperature of quartz; and b) form compounds that are thermally stable at temperatures of above 1400° C. and chemically stable in a SiO₂ environment. A method to make a crucible having controlled bubble content is also disclosed, the method comprises the step of forming a crucible having an inner layer doped with a material that reacts with residual gases in the bubble such as nitrogen and oxygen and thus consume the gases in the bubbles and empty them in the fusion process.

### CROSS REFERENCE TO RELATED APPLICATIONS

This application claims priority to U.S. Provisional Application Serial No. 60/526,484 filed on Dec. 3, 2003, which is incorporated herein by reference in its entirety.

### FIELD OF THE INVENTION

The present invention relates to fused quartz crucible for use in the semi-conductor industry for growing single crystal silicon, and a method for reducing the concentration of near-surface bubbles in quartz crucibles used in the growing of single crystal silicon.

### BACKGROUND OF THE INVENTION

Single crystal silicon, which is the starting material for most semiconductor electronic component fabrication, is commonly prepared by the so-called Czochralski (“Cz”) method. Using the Cz method, the growth of the crystal is most commonly carried out in a crystal pulling furnace, wherein polycrystalline silicon (“polysilicon”) is charged to a crucible and melted by a heater surrounding the outer surface of the crucible side wall. A seed crystal is brought into contact with the molten silicon and a single crystal ingot is grown by extraction via a crystal puller.

Crucibles used in conventional crystal pullers are commonly constructed of quartz because of its purity, temperature stability and chemical resistance. A method for making quartz crucible is disclosed in U.S. Pat. No. 4,416,680, wherein a raw quartz material is introduced into a rotating hollow mold. After the introduction of the raw material, a heat source such as an electric arc is introduced into the mold which causes the quartz to melt. Simultaneously with the heating, a vacuum is applied to the outside of the mold during continued rotation to draw out any interstitial gases, with an aim toward collapsing the voids. The vacuum is maintained during melting and rotation. Thereafter, the finished crucible may be ejected by replacing the vacuum with compressed air outside the mold. In the process, residual gases such as carbon, hydroxyl groups, and the like, can cause unwanted bubbles to form in the quartz glass.

In the crystal growing process, the prolonged exposure of the inside crucible side wall with the high temperature silicon melt results in reaction of the silicon melt with the quartz crucible and leads to the dissolution of the inner surface of the crucible side wall. This exposes bubbles in the crucible side wall to the molten silicon. As a result, the silicon melt continues to dissolve into the wall of the crucible, and as a consequence dissolves into the walls of the bubbles. At some point, the walls of the bubbles are breached and the walls may cave in, simultaneous to the releasing of gases from inside the bubbles and quartz particles from the crucible and/or bubble sidewall into the melt. In so doing, particles can destroy the single crystal structure, thus limiting the crystal growing single crystal yield. In addition, the presence of the bubble cavities or bubble voids along the inside surface of the crucible may be sites for gas nucleation. When gases nucleate and grow into small bubbles, those bubbles may find their way into the growing silicon causing crystals with voids, not meeting specifications. The reduction or elimination of the bubbles in the crucible will ensure that voids in the crystal are minimized, for acceptable crystal performance within specifications.

There are various approaches to address the issue of bubbles in crucible walls. U.S. Pat. Nos. 4,935,046 and 4,956,208 call for the deposition of a layer of SiCl₄ on the crucible surface by chemical vapor deposition. U.S. patent application No. 20020166341 teaches the use of a fast diffusing gas such as helium or hydrogen through the quartz sand to displace the residual gases present in the voids defined by the quartz sand. U.S. Pat. No. 6,187,079 discloses a process for producing a quartz crucible having a tungsten doped layer for a crucible which behaves similarly to a bubble free layer. The doping is via one of a) a tungsten vapor source for the tungsten to diffuse into the inside surface of the crucible; b) the application of a solution of a tungsten compound in an organic solvent; or c) mixing a precursor solution of tungsten in silica, for a layer of at least 100 ppba on the inside surface of the crucible. Patent Application No. EPO 693461A1 discloses a different method to make a quartz crucible that is free of aggregates of fine bubbles and high purity, by controlling the amount of copper, chromium, and nickel in the SiO₂ feed to 0.5 ppb or less, iron to 120 ppb or less and sodium to 20 ppb or less.

There is still a need for a method to control bubbles/improve bubble stability in quartz crucibles for use in the crystal growing process.

### BRIEF SUMMARY OF THE INVENTION

The invention relates to a method to control bubbles/improve bubble stability in quartz crucible by doping the crucible with elements and compounds that: a) react with oxygen and nitrogen at or near the fusion temperature of quartz; and b) form compounds that are thermally stable at temperatures of above 1500° C. and chemically stable in a SiO₂ environment. In one embodiment, only the inner layer of the crucible is doped.

In one embodiment of the invention, said elements and compounds are selected from the group consisting of: aluminum, titanium, chromium, iron, zinc, molybdenum, magnesium, calcium, scandium, yttrium, lanthanum, zirconium, hafnium, cerium, vanadium, niobium, tantalum, their suboxides and subnitrides thereof.

The invention further relates to a quartz crucible doped with elements and compounds that: a) react with oxygen, nitrogen, carbon monoxide and carbon dioxide at or near the fusion temperature of quartz; and b) form compounds that are thermally stable at temperatures above 1400° C. and chemically stable in a SiO₂ environment.

In one embodiment of the invention, the quartz crucible comprises an outer layer portion or layer of undoped crystalline quartz, and an inner lining made from synthetic or natural crystalline quartz, and wherein only the inner layer of the quartz crucible is doped.

In another embodiment of the invention, the quartz crucible or its inner layer is doped with tantalum powder having a size of about 50 microns or less, for a dopant concentration of about 50 to 500 ppmw.

### BRIEF DESCRIPTION OF THE DRAWING

FIG. 1 is a schematic of an apparatus suitable the formation of a doped quartz crucible of the present invention.

### DETAILED DESCRIPTION OF THE INVENTION

Applicants have developed a novel process for controlling/improving bubble stability in quartz crucibles using apparatuses known in the art.

As used herein, sand mass, synthetic sand, silica grain, synthetic silica grain, natural quartz, quartz sand, and silicon dioxide are used interchangeably to describe the crystalline quartz raw materials (from synthetic or natural sources) for forming fused quartz crucibles. The raw materials may be of a size ranging from 10 to 500 microns, with an average coarse grain size of approximately 200 microns. The raw materials may further comprise materials such as alkali metals, alkaline earth metals, silica rock, silica sand, α-quartz, cristobalite, and the like.

In one embodiment of the invention, the quartz crucible has an outer layer of quartz glass and an inner layer of a different quartz glass material, e.g., an outer layer of natural quartz material and an inner layer of a synthetic quartz material. In another embodiment, the crucible is of the same material obtained by melting and casting quartz material, either synthetic or natural quartz, using arc heating.

As used herein, the “inner layer” refers to the interior surface region of a quartz crucible, or the layer that would be in contact with a molten semiconductor material, which would be used for growing crystalline semi-conductor materials, e.g., silicon crystal growth. The inner layer may be the inner layer of a single-layer quartz crucible (in contact with the molten semiconductor material) or the inner layer of a crucible having at least two ore more different layers of different quartz materials/compositions.

Applicants have found that by doping the inner layer of the crucible of the invention with certain selected materials, the materials react with residual gases in the bubble such as nitrogen and oxygen and thus consume the gases in the bubbles and empty them in the fusion process. This effectively enables the bubbles to collapse or be collapsed.

The doping materials are selected such that the nitrides and oxides formed are stable in the temperatures ranges wherein the crucible are formed and/or stable in the temperature ranges wherein the crucibles are used, i.e., of or above 1400° C. In one embodiment, the doping materials are selected such that nitride and oxide compounds formed are thermally stable at temperatures of above 1420° C. In yet another embodiment, the materials are selected for temperatures of above 1450° C.

In one embodiment, the dopants are powder materials having a size of about 50 microns or less. In another embodiment, the dopants are powders of a size of 30 microns or less.

Examples of doping materials include metallic aluminum, metallic titanium, metallic tantalum, metallic zirconium, metallic hafnium, metallic vanadium, metallic niobium, metallic chromium, metallic zinc, metallic cadmium, suboxides and subnitrides, partially oxidized materials, partially nitrided materials, and combinations thereof. Examples of a suboxide include Ce₂O₃, VO, VO2, or TiO. Examples of a combination include alloys such as TaNb.

Doping materials are readily available commercially. Examples include high purity or ultra high purity metal powders having a size of about 50 microns or less, fused metal oxide and suboxide powders of high purity having a size of 5 microns or less, commercially available from Atlantic Equipment Engineers at www.micronmetals.com, Johnson Matthey Alfa-Aesar, and other suppliers.

The dopant is added in an amount such that the level is sufficiently low enough for the dopant not to affect the crystal properties, but sufficiently high enough to affect the crucible bubble structure and thus help with the single crystal yield. In one embodiment, the dopant is added in an amount for a concentration of about 75 ppm by weight (ppmw) to about 500 ppmw in the inner crucible layer. In another embodiment, it is added in a sufficient amount for a concentration of about 100 ppmw to about 400 ppmw in the inner crucible layer. In a third embodiment, the amount is above 100 ppmw. In a fourth embodiment, the amount is 400 ppmw or less.

The dopant can be added to the quartz sand feed before fusion to form the inner layer of the crucible, or it can be diffused into the crucible after fusion so as to provide a presence of the dopant on the inner layer of the crucible.

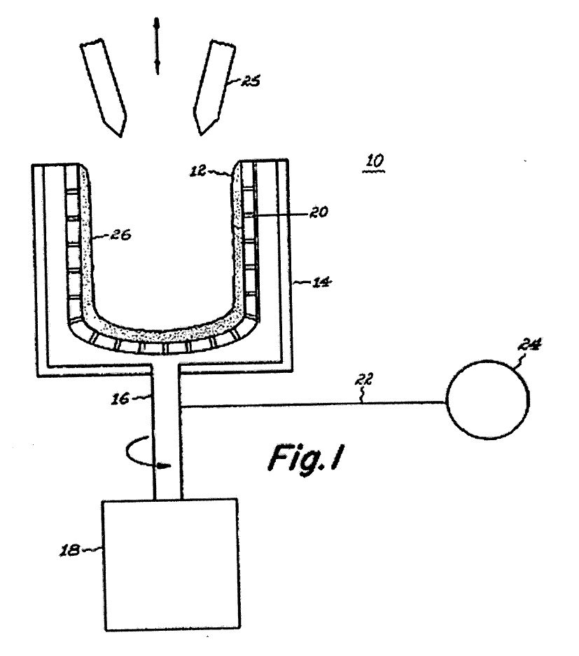

FIG. 1 is a schematic of one embodiment of an apparatus 10 for forming a fused quartz crucible 12, the apparatus is more fully described in U.S. Pat. No. 4,416,680. In the fusing process, crystalline quartz raw materials are admitted into a hollow rotating mold shell to form the crucible shape and thereafter fused with an electric arc.

In FIG. 1, a hollow metal shell mold 14 is rotably mounted upon shaft 16 to provide the means in each the fusion of the quartz crucible takes place. A motor drive member 18 rotates the fusion housing assembly to hold the quartz sand mass against the inner walls of the metal shell 14 by centrifugal force. Perforations 20 are provided to the inner walls of the shell 14 so that fusion of the shaped sand mass can take place under vacuum conditions to reduce the bubble content in the fused quartz member. Such vacuum operation is achieved by connecting a supply conduit 22 that leads from the metal shell 14 to a vacuum pump 24.

An electrode assembly 25 comprising a power source and electrodes (not shown) is movably mounted about the metal shell 14 to provide a suitable heat source which melts the quartz sand shape contained within the shell 14.

In operations, a quantity of quartz sand is deposited in the metal shell 14, which is rotated to form a porous shape 26 having the crucible configuration. Vacuum pump 24 exhausts air from the porous sand shape during its subsequent fusion with an electric arc that is provided by the associated electrode assembly. The electrode assembly can be programmed to automatically descend within the metal shell during the fusion step, while being withdrawn to its original elevation after the fused quartz vessel has been formed. After the fusion is complete and the part formed, the fused part is cooled and removed from the fusion container. After the removal, the entire assembly can be prepared for the next batch cycle.

In one embodiment of the invention (not shown), the perforations 20 are in the form of uniformly spaced ports around shell 14, permitting the passing of helium or hydrogen (instead of air) through the quartz sand. Once the crucible inner wall forms a skin, the helium or hydrogen helps displace other gases that may be present in the void. A series of openings or ports at the bottom of shell 14 supply a vacuum, thus creating a flow to pull the residual gases in the sand.

In one embodiment of the invention to manufacture a crucible having an outer undoped layer of quartz glass and an inner layer of “doped” quartz glass with stabilized/controlled bubble density, “pure” or undoped quartz sand material is first fed via grain hoppers (not shown) into the mold 14. There may be multiple metered grain hoppers for the feeding of the doped and undoped quartz sand feed streams. The metal hopper is equipped with a feed tube and a valve to meter the follow of quartz sand from the hopper to the interior of the metal mold 14. Rotation of the mold 14 by motor drive 18 provides sufficient force to retain the poured silica grain on the inner surface of the mold 14. A spatula (not shown), shaped to confirm to the inner surface of the shell mold 14, is generally used to shape the outer layer and/or sand feed. In this matter, the crucible layer can be formed to a selected thickness, in one example, a thickness of approximately 0.875 inches

In one embodiment of the invention, an electric arc is produced between the electrodes of the assembly 25. A region of heat is thereby generated within the interior of the metal shell 14 with the temperature of the silica grain reaching to 1800-2200° C. The heat serves to fuse the silica grain in the mold. Fusion proceeds through the grain from proximal (inner or nearest surface) to the distal or further surface relative to the electrodes of the assembly 25. The mechanism of progressive fusion through the silica grain layer is known to those skilled in the art.

In one embodiment of the fusion step, the backing sand is poured into position in the fusion mold 14 with the mold shape, geometry, and other fusion details being known to those skilled in the art. After this backing sand is in position in the spinning mold, the lining sand is poured into place in a similar manner. As used herein, the lining sand is the sand, which is doped with the additive(s) of the invention in order to control and improve the bubble density and stability. Once all of the sand is in place in the spinning mold, the arc is struck between the electrode tips and the sand is fused into a solid fused silica body for a fused crucible useful in the semiconductor industry.

In another embodiment of the fusion step, all of the sand is poured into position in the fusion mold 14 for the entire sand pre-form to be made using the doped sand, i.e., the additive to the sand is present in all of the sand in the mold. Once all of the sand is in place in the spinning mold, the arc is struck between the electrode tips and the sand is fused into a solid fused silica body for a fused crucible useful in the semiconductor industry.

In yet another embodiment of the fusion step, the backing sand is poured into position and the backing sand is fused into a solid fused silica crucible body. After fusion of the outer layer, the inner layer is formed next. In this embodiment, silica grain with the dopants of the present invention is poured from the inner silica grain hopper through the feed tube and regulating valve into mold 14 with formed outer layer. The arc produced between the electrodes of assembly 25 creates a strong plasma field, propelling the partially melted inner silica grain outward, enabling it to be deposited onto the sides and bottom of the surface of mold 14, i.e., the inner surface of the outer crucible layer. The inner grain as partially melted by the arc flame is deposited and fused to the outer crucible layer, thus forming the inner layer of desired thickness. In one embodiment, the thickness of the inner layer is about 0.5 mm to 7 mm.

After formation of the inner layer by the deposition of the doped silica grain and fusion step discussed above, the crucible is cooled for about ˜30-90 seconds or more for sufficient structural rigidity to permit removal from the mold 14 without deformation. In another embodiment, the crucible can be held at a selected temperature for a selected period or time, or the crucible can be cooled at a controlled rate.

In another embodiment to manufacture a quartz crucible of a single layer of doped quartz material, the silica grain is first doped, i.e., the dopant additive is present in all of the sand feed. The doped quartz powder is then melted and sintered with a high-powered arc and molded into a crucible, for an inner layer with stabilized/controlled bubble density.

In one embodiment, in lieu of (or in addition to) dopants in the silica grain feed, the fused crucible as formed by the deposition of the silica grain in the steps above may be placed into a furnace chamber for about 20 minutes to about 10 hours, wherein the atmosphere of the chamber is saturated with the dopant materials of the invention, e.g., Mo vapor or Mo₂O₅ vapor for example, which then contacts the surfaces of the crucible and diffuses into the quartz, giving additional treatment time and dopant concentration to control/stabilize/reduce bubble formation in the inner crucible layer.

Final processing steps of the invention may include fine sanding or polishing of the crucible exterior surface, edge cutting, cleaning, and packaging to protect the crucible.

In one embodiment, the crucible has a depth or thickness of about 8 mm to about 25 mm that is uniformly doped with the dopant of the invention. In another embodiment, the maximum thickness is 20 mm. In another embodiment, the crucible has an outer undoped layer of 5 mm to 20 mm, and a doped lining layer of about 3 mm to about 20 mm. In yet a embodiment, the crucible has an outer undoped layer having a thickness or depth of about 0.5 to 12 mm, and a doped inner layer with a depth from 1 to 10 mm.

In one embodiment of the invention, the crucible has an inner layer or at least an interior surface portion having an average bubble volume density ratio of less than 0.003, measured as the ratio of the volume of the bubbles over the volume of a crucible sample section. The sample section is obtained at a depth of 1 to 2 mm from the interior surface in contact with the semiconductor material melt. In a second embodiment, the layer has average bubble density ratio of less than 0.002. In a third embodiment, the crucible has average bubble density ratio of less than 0.001. In a fourth embodiment, the crucible has a bubble density ratio of <0.00075.

### EXAMPLES

Examples are provided herein to illustrate the invention but are not intended to limit the scope of the invention.

### Example 1

Four crucibles A, B, C, D, and E are made to similar dimensions of nominal diameter of 22 inches each. All crucibles are made with similar outer layer comprising pure natural silica grain. The inner layer of all crucibles also comprises natural silica grain. If doping is required, the doping is done via processes known in the art, e.g., silica grain and dopant(s) in measured quantities are placed in a plastic bottle and put into a Turbula solids mixer and tumbled for about 30 minutes. The mixture is further diluted by placing this dopant premix into a larger container, e.g. a barrel, with a larger quantity of undoped sand. This heterogeneous mixture is then blended and homogenized by further tumbling. The procedure may be repeated until the desired dopant concentration is obtained.

In this example, crucible A is made according to the teaching of U.S. Pat. No. 4,911,896, with the upper wall region of the inner crucible layer further containing 50 ppm by weight of fine size spherically shaped silicon metal crystals of 350 mesh size, and with the total metal content in the inner layer of the crucible is kept at 100 ppm or less.

The entire inner layer of Crucible B is doped with 300 ppm by weight of tantalum powder from Atlantic Equipment Engineers (“AEE”) with 99.8% purity and 1-5 micron particle size.

The entire inner layer of Crucible C is doped with 250 ppm by weight of aluminum powder, white to gray hexagonal crystals, also from AEE, having a particle size of 1-5 micron.

The entire inner layer of Crucible D is doped with 200 ppm by weight of niobium powder, white to gray hexagonal crystals, also from AEE, having a particle size of 1-5 micron.

With respect to Crucible E, a crucible with an un-doped inner layer commercially available from General Electric Company as “V3B” is further annealed for 1 hr in a furnace chamber saturated with a metal vapor such as Tantalum for 1 hr. for a dopant concentration of at least about 100 ppm.

Crucibles A-E are subject to a vacuum bake process simulating a CZ-process, after which the inner layer of each crucible is examined. The inner surface region of Crucibles B, C, D, and E, each presents a lining region where there is less than normal bubble growth. The bubble growth is more limited both in terms of the number of bubbles that form and in terms of the growth in size of bubbles already formed, or formed from nuclei during use. Crucible A in contrast, is observed to have more bubble growth in terms of the number of bubbles and also in terms of the amount of growth in size of the bubbles which are present in the region of the inner layer.

### Example 2

In this example, Crucibles are made using tantulum doping as previously described for Crucible B at a concentration of 200 ppm, 250 ppm, and 300 ppm, and labeled as B′, C′, and D′. Crucible A′ is commercially available from General Electric Company as V3B.

Coupons of 1″ by 2″ sliced from Crucibles A′- D′ are baked at 1560° C. for 24 hours. Digital images are obtained using optical microscopy so that the bubble “amount” or volume can be quantified. The bubbles are counted and measured manually from subsections of 1″ by 2″ by 1 millimeter. In various sections of the coupons, it is observed that the bubble count in the doped Crucibles B′-D′ is about ⅕ of the count in the undoped Crucible A′. The bubble density ratios are measured as previously described, with the results averaging the bubble volume density ratios as follows.

| Sample | Bubble volume/Total Volume |
|---|---|
| A′ | 0.009707 |
| B′ | 0.000764 |
| C′ | 0.001004 |
| D′ | 0.000532 |

While the invention has been described with reference to a preferred embodiment, those skilled in the art will understand that various changes may be made and equivalents may be substituted for elements thereof without departing from the scope of the invention. It is intended that the invention not be limited to the particular embodiment disclosed as the best mode for carrying out this invention, but that the invention will include all embodiments falling within the scope of the appended claims.

All citations referred herein are expressly incorporated herein by reference.

1. A quartz glass crucible for pulling a silicon single crystal, said crucible comprising an interior surface portion of quartz glass doped with a metal powder that: a) reacts with oxygen and nitrogen to form a metal oxide or a metal nitride; and b) forms compounds that are thermally stable at temperatures of above 1400° C. and chemically stable in a SiO₂ environment.

2. The quartz glass crucible of claim 1 for pulling a silicon single crystal, wherein said crucible comprising a single layer of quartz glass doped with said metal powder.

3. The quartz glass crucible of claim 1 for pulling a silicon single crystal, wherein said crucible comprising:
an outer layer of quartz glass;
an inner layer of quartz glass having an interior surface portion doped with said metal powder.

4. The quartz glass crucible of claim 2, wherein said inner layer of quartz glass is doped with said metal powder.

5. The quartz glass crucible of claim 1, wherein said interior surface portion is doped with a metal suboxide or a metal subnitride.

6. The quartz glass crucible of claim 1, wherein said interior surface portion is doped with tantalum powder in the range of 50 to 500 ppmw.

7. The quartz glass crucible of claim 1, wherein said interior surface portion is doped with a metal powder having an average size of less than 40 microns.

8. The quartz glass crucible of claim 1, wherein said inner layer of quartz glass is doped with a metal powder such as tantalum, niobium, vanadium, aluminum, titanium, chromium, iron, zinc, magnesium, and calcium.

9. A quartz glass crucible for pulling a silicon single crystal having a bubble volume density of less than 0.003 at a depth of 1 to 2 mm from an interior surface.

10. The quartz glass crucible of claim 9, wherein said crucible has a bubble volume density of less than 0.002 at a depth of 1 to 2 mm from an interior surface.

11. The quartz glass crucible of claim 10, wherein said crucible has a bubble volume density of less than 0.001 at a depth of 1 to 2 mm from an interior surface.

12. A method for making a quartz glass crucible for pulling a silicon single crystal, said method comprising the step of molding a crucible having an interior surface portion comprising silica grain doped with a metal powder that: a) reacts with oxygen and nitrogen to form a metal oxide or a metal nitride; and b) forms compounds that are thermally stable at temperatures of above 1400° C. and chemically stable in a SiO₂ environment.

13. The method of claim 12, wherein said crucible has a bubble volume density of less than 0.003 at a depth of 1 to 2 mm from an interior surface.

14. The method of claim 13, wherein said crucible has a bubble volume density of less than 0.002 at a depth of 1 to 2 mm from an interior surface.

15. The method of claim 12, wherein said quartz glass crucible has an inner layer and an outer layer, and wherein said molding comprises the steps of:
forming said outer layer on an interior surface of a rotating crucible mold;
introducing into said rotating crucible mold silica grain doped with a metal powder that: a) reacts with oxygen and nitrogen to form a metal oxide or a metal nitride; and b) forms compounds that are thermally stable at temperatures of above 1400° C. and chemically stable in a SiO₂ environment;
generating a region of heat in the interior of the rotating crucible wherein the region of heat at least partially melts said doped silica grain and fuses said at least partially molten silica grain onto said outer layer, forming the inner layer.

16. The method of claim 12, wherein said silica grain is doped with a metal suboxide or a metal subnitride.

17. The method of claim 12, wherein said silica grain is doped with tantalum powder in the range of 50 to 400 ppmw.

18. The method of claim 12, further comprising the step of placing said quartz glass crucible into a furnace chamber wherein the atmosphere of the chamber is saturated with a material that a) reacts with oxygen and nitrogen to form a metal oxide or a metal nitride; and b) forms compounds that are thermally stable at temperatures of above 1400° C. and chemically stable in a SiO₂ environment.

19. The method of claim 12, wherein the silica grain consists essentially of pure natural silica glass.

20. The method of claim 12, wherein the silica grain consists essentially of pure synthetic silica glass.
